(19) United States
(12) Patent Application Publication
(10) Pub. No.: US 2025/0364357 A1
(43) Pub. Date: Nov. 27, 2025

(54) ELECTRONIC PACKAGE

(71) Applicant: SILICONWARE PRECISION INDUSTRIES CO., LTD., Taichung City (TW)

(72) Inventors: Chi-Wei WEN, Taichung City (TW); Chih-Hung CHEN, Taichung City (TW); Shu-Ping YANG, Taichung City (TW); Liang-Pin CHEN, Taichung City (TW)

(73) Assignee: SILICONWARE PRECISION INDUSTRIES CO., LTD., Taichung City (TW)

(21) Appl. No.: 18/824,512

(22) Filed: Sep. 4, 2024

(30) Foreign Application Priority Data
May 23, 2024 (TW) 113119164

(51) Int. Cl. H01L 23/367; H01L 23/00; H01L 23/538; H01L 25/065

(52) U.S. Cl. CPC H01L 23/3677; H01L 24/16; H01L 24/32; H01L 24/73; H01L 23/5386; H01L 25/0655; H01L 2224/16225; H01L 2224/32225; H01L 2224/73204; H01L 2924/19105

(57) ABSTRACT

The present disclosure provides an electronic package including: a carrier structure having a circuit layer, a first electronic component disposed on the carrier structure and electrically connected to the circuit layer, and a thermal conductive layer applied to the first electronic component and the carrier structure. The present disclosure replaces the conventional method of using heat sinks by coating a thermal conductive layer such as a metal layer, thereby avoiding problems of the heat sink occupying a position of the carrier structure and the heat sink falling off.

### BACKGROUND

### 1. Technical Field

The present disclosure relates to a semiconductor packaging structure, and more particularly, to a heat dissipation type electronic package.

### 2. Description of Related Art

As the demand for functionality and processing speed of electronic products increases, semiconductor chips, which are the core components of electronic products, need to have a higher density of electronic components and electronic circuits. Therefore, the semiconductor chips will generate a larger amount of heat energy during operation.

In order to quickly dissipate heat energy to the outside, the industry usually configures a heat sink in a semiconductor package to dissipate the heat generated by the semiconductor chip via the heat sink.

As shown in FIG. 1, in a conventional method for manufacturing a semiconductor package 1, a semiconductor chip 11 is first mounted on a package substrate 10 using a flip-chip bonding method, a heat sink 13 covers the semiconductor chip 11 with a top sheet 130 of the heat sink 13, and a supporting leg 131 of the heat sink 13 are mounted on the package substrate 10 via an adhesive layer 14. During operation, the heat energy generated by the semiconductor chip 11 is conducted to the top sheet 130 of the heat sink 13 to dissipate heat to the outside of the semiconductor package 1.

However, in order to improve the operating performance of the semiconductor package, a passive component 12 is added to the package substrate 10, so that the area available for bonding to the heat sink 13 (supporting leg 131) on the package substrate 10 is reduced. Therefore, it is difficult for the heat sink 13 to be firmly attached and positioned on the package substrate 10, and the heat sink 13 may fall off.

Furthermore, it may also cause the problem of the heat sink 13 falling off when the package substrate 10 provided with the heat sink 13 is subjected to external forces such as vibration or collision. Alternatively, the adhesive layer 14 for attaching the heat sink 13 and the package substrate 10 may easily cause delamination between the heat sink 13 and the package substrate 10 due to stress, thereby causing the heat sink 13 to fall off.

Therefore, how to overcome the above-mentioned drawbacks of the prior art has become an urgent issue to be solved.

### SUMMARY

In view of the various deficiencies of the prior art, the present disclosure provides an electronic package including: a carrier structure; a first electronic component disposed on the carrier structure; and a thermal conductive layer contacting and covering the first electronic component and the carrier structure.

In the aforementioned electronic package, the carrier structure has a first surface and a second surface opposite to the first surface, and a primary component connection area and a secondary component connection area are defined on the first surface.

In the aforementioned electronic package, the first electronic component has an active surface and a non-active surface opposite to the active surface, and the first electronic component is disposed through the active surface in the primary component connection area of the carrier structure via a plurality of conductive bumps.

In the aforementioned electronic package, the present disclosure further comprises an underfill formed between the carrier structure and the first electronic component to cover the plurality of conductive bumps.

In the aforementioned electronic package, the thermal conductive layer contacts and covers the non-active surface of the first electronic component.

In the aforementioned electronic package, the present disclosure further comprises a second electronic component disposed in the secondary component connection area of the carrier structure.

In the aforementioned electronic package, the thermal conductive layer is formed with an opening exposing the second electronic component.

In the aforementioned electronic package, the second electronic component is a passive component.

In the aforementioned electronic package, the present disclosure further comprises a plurality of conductive components implanted on the second surface of the carrier structure.

In the aforementioned electronic package, the thermal conductive layer contacts and covers the first electronic component and the carrier structure by coating a metal layer with high thermal conductivity.

In the aforementioned electronic package, the thermal conductive layer is defined with a first area and a second area, the first area corresponds to an area on the carrier structure where the first electronic component is disposed, and the second area corresponds to an area of the carrier structure where the first electronic component is not disposed.

In the aforementioned electronic package, a thickness of the thermal conductive layer in the first area is smaller than a thickness of the thermal conductive layer in the second area.

In the aforementioned electronic package, a ratio of the thickness of the thermal conductive layer in the first area to the thickness of the thermal conductive layer in the second area is 1:10.

In the aforementioned electronic package, a material of the thermal conductive layer located in the first area is different from a material of the thermal conductive layer located in the second area.

Therefore, in the electronic package of the present disclosure, the thermal conductive layer (the metal layer) is coated on the carrier structure where the electronic components are connected for contacting and covering the electronic components and the carrier structure. Since the metal layer is thinner and provides a better heat dissipation effect, the conventional method of using heat sinks can be replaced, thereby the space used by the carrier structure can be saved. In addition, the passive component is conventionally added on the package substrate, causing the area on the package substrate available for bonding the heat sink is reduced, it is thus difficult for the heat sink to securely attach and position, or the heat sink may fall off when the package substrate is subjected to an external force or the adhesive layer attaching the heat sink and the package substrate is shaken or collided, and these problems can be overcome by the aforementioned configuration of the thermal conductive (i.e., the metal layer) layer in the electronic package of the present disclosure.

### BRIEF DESCRIPTION OF THE DRAWINGS

FIG. 1 is a schematic cross-sectional view of a conventional semiconductor package.

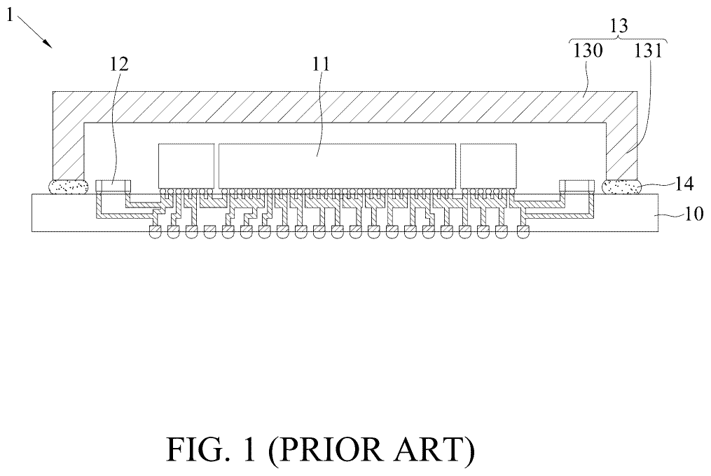

FIG. 2 is a schematic cross-sectional view of an electronic package according to the present disclosure.

FIG. 3 is a top view of the electronic package according to the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

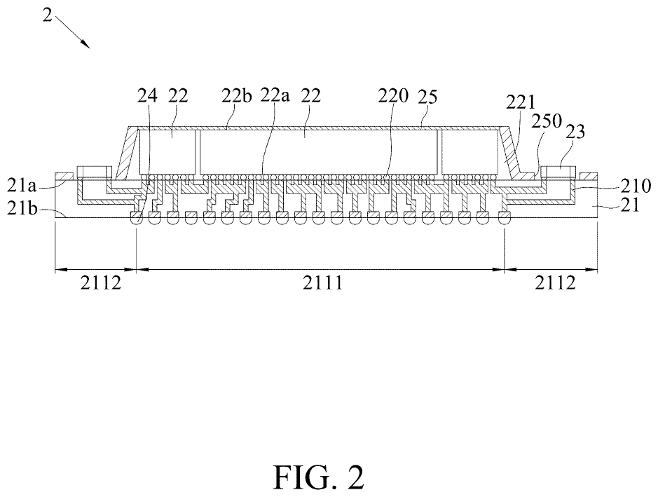

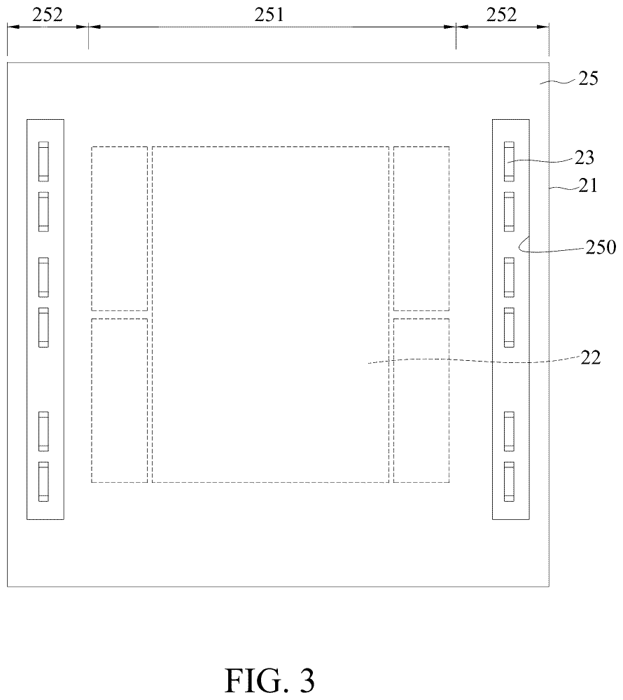

Please refer to FIGS. 2 and 3. FIG. 2 is a schematic cross-sectional view of an electronic package 2 according to the present disclosure, and FIG. 3 is a schematic top view of the electronic package 2 according to the present disclosure. In the electronic package 2 of the present disclosure, at least one first electronic component 22 is disposed on a carrier structure 21, and a thermal conductive layer 25 is in contact with and covers the first electronic component 22 and the carrier structure 21.

The carrier structure 21 has s first surface 21a, a second surface 21b opposite to the first surface 21a, and a circuit layer 210, and a primary component connection area 2111 and a secondary component connection area 2112 are defined on the first surface 21a.

In one embodiment, the carrier structure 21 is, for example, a package substrate, and the circuit layer 210 is, for example, a redistribution layer (RDL).

The first electronic component 22 is, for example, an active component (such as a semiconductor chip) or a package module.

In one embodiment, a plurality of the first electronic components 22 are disposed on the carrier structure 21. Each of the first electronic components 22 is, for example, a semiconductor chip and has the active surface 22a and the non-active surface 22b opposite to the active surface 22a. The active surface 22a is disposed in the primary component connection area 2111 of the carrier structure 21 via a plurality of conductive bumps 220 in a flip-chip manner and is electrically connected to the circuit layer 210. In addition, an underfill 221 is formed between the first surface 21a of the carrier structure 21 and the first electronic components 22 to cover each of the conductive bumps 220. However, there are several ways to electrically connect the first electronic components 22 to the carrier structure 21, and the present disclosure is not limited to as such.

Furthermore, at least one or a plurality of second electronic components 23 can be connected to the secondary component connection area 2112 of the first surface 21a of the carrier structure 21, and the second electronic component 23 is a passive component (such as a resistor, a capacitor or an inductor).

In addition, a plurality of conductive components 24 such as solder bumps or solder balls can be implanted on the second surface 21b of the carrier structure 21, and the plurality of conductive components 24 are electrically connected to the circuit layer 210.

The thermal conductive layer 25 contacts and covers the first electronic components 22 and the carrier structure 21 by, for example, coating a metal layer (such as copper, gold, aluminum) with a high thermal conductivity, so that the thermal conductive layer 25 (metal layer) is thinner and provides a better heat dissipation effect, thereby replacing the conventional method of using a heat sink.

In particular, a distribution range of the thermal conductive layer 25 is defined with a first area 251 and a second area 252, the first area 251 corresponds to an area where the first electronic component 22 is provided on the carrier structure 21, that is, corresponds to the primary component connection area 2111 of the carrier structure 21, and the second area 252 corresponds to an area of the carrier structure 21 where the first electronic component 22 is not disposed, that is, corresponds to the secondary component connection area 2112 of the carrier structure 21. The thickness of the thermal conductive layer 25 located in the first area 251 is smaller than the thickness of the thermal conductive layer 25 located in the second area 252, for example, the thickness ratio is 1:10. Furthermore, the material of the thermal conductive layer 25 disposed on the first area 251 may be the same as or different from the material of the thermal conductive layer 25 disposed on the second area 252.

In addition, the thermal conductive layer 25 disposed on the carrier structure 21 can be formed with an opening 250 corresponding to the secondary component connection area 2112 (i.e., the second area 252 of the thermal conductive layer 25) of the first surface 21a of the carrier structure 21, so that a plurality of second electronic components 23 are exposed from the thermal conductive layer 25 to prevent the thermal conductive layer 25 from contacting the second electronic components 23 and causing a short circuit problem.

To sum up, in the electronic package of the present disclosure, the thermal conductive layer (metal layer) is coated on the carrier structure where the electronic components are connected, so that the metal layer contacts and covers the electronic components and the carrier structure. Since the metal layer is thinner and provides a better heat dissipation effect, the conventional method of using heat sinks can be substituted, and thus the space used by the carrier structure can be saved. In addition, the passive component is conventionally added on the package substrate, causing the area on the package substrate available for bonding the heat sink is reduced, it is thus difficult for the heat sink to securely attach and position, or the heat sink may fall off when the package substrate is subjected to an external force or the adhesive layer attaching the heat sink and the package substrate is shaken or collided, and these problems can be overcome by the aforementioned configuration of the thermal conductive (i.e., the metal layer) layer in the electronic package of the present disclosure.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure;
a first electronic component disposed on the carrier structure; and
a thermal conductive layer contacting and covering the first electronic component and the carrier structure.

2. The electronic package of claim 1, wherein the carrier structure has a first surface and a second surface opposite to the first surface, and a primary component connection area and a secondary component connection area are defined on the first surface.

3. The electronic package of claim 2, wherein the first electronic component has an active surface and a non-active surface opposite to the active surface, and the first electronic component is disposed through the active surface thereof in the primary component connection area of the carrier structure via a plurality of conductive bumps.

4. The electronic package of claim 3, further comprising an underfill formed between the carrier structure and the first electronic component to cover the plurality of conductive bumps.

5. The electronic package of claim 3, wherein the thermal conductive layer contacts and covers the non-active surface of the first electronic component.

6. The electronic package of claim 2, further comprising a second electronic component disposed in the secondary component connection area of the carrier structure.

7. The electronic package of claim 6, wherein the thermal conductive layer is formed with an opening exposing the second electronic component.

8. The electronic package of claim 6, wherein the second electronic component is a passive component.

9. The electronic package of claim 2, further comprising a plurality of conductive components implanted on the second surface of the carrier structure.

10. The electronic package of claim 1, wherein the thermal conductive layer contacts and covers the first electronic component and the carrier structure by coating a metal layer with a high thermal conductivity.

11. The electronic package of claim 1, wherein the thermal conductive layer is defined with a first area and a second area, the first area corresponds to an area on the carrier structure where the first electronic component is disposed, and the second area corresponds to an area of the carrier structure where the first electronic component is not disposed.

12. The electronic package of claim 11, wherein a thickness of the thermal conductive layer in the first area is smaller than a thickness of the thermal conductive layer in the second area.

13. The electronic package of claim 11, wherein a ratio of the thickness of the thermal conductive layer in the first area to the thickness of the thermal conductive layer in the second area is 1:10.

14. The electronic package of claim 11, wherein a material of the thermal conductive layer located in the first area is different from a material of the thermal conductive layer located in the second area.
